(19) United States
(12) Patent Application Publication
(10) Pub. No.: US 2010/0233638 A1
(43) Pub. Date: Sep. 16, 2010

(54) SUBSTRATE TREATMENT APPARATUS, SUBSTRATE TREATMENT METHOD, COATING AND DEVELOPING APPARATUS, COATING AND DEVELOPING METHOD, AND STORAGE MEDIUM

(75) Inventors: Yuichi YOSHIDA, Koshi-Shi (JP); Hiroshi ARIMA, Koshi-Shi (JP); Taro YAMAMOTO, Koshi-Shi (JP); Kousuke YOSHIHARA, Koshi-Shi (JP)

Correspondence Address: BURR & BROWN, PO BOX 7068, SYRACUSE, NY, 13261-7068, US

(73) Assignee: Tokyo Electron Limited, Minato-ku (JP)

(21) Appl. No.: 12/720,072

(22) Filed: Mar. 9, 2010

(30) Foreign Application Priority Data
Mar. 13, 2009 (JP) 2009-062088

(51) Int. Cl. G03F 7/20; G03B 27/42

(52) U.S. Cl. 430/325; 355/53

(57) ABSTRACT

The substrate treatment apparatus includes a heating plate that heats the substrate prepared by coating a surface of the substrate with a resist and exposing the resist-coated substrate to light; a surface treatment liquid atomizing unit that atomizes a surface treatment liquid used to improve wettability of the substrate with a developer that is supplied onto the resist; a cooling unit that cools the substrate heated by the heating plate; and a surface treatment liquid supply unit that supplies the atomized surface treatment liquid onto the substrate for a portion of the period from the time when the substrate is heated until the cooling means terminates the cooling of the substrate.

### CROSS-REFERENCE TO THE RELATED APPLICATION

The present application claims priority from Japanese application No JP2009-062088, filed on Mar. 13, 2009, the content of which is hereby incorporated by reference into this application.

### BACKGROUND OF THE INVENTION

1. Field of the Invention

The present invention relates to a substrate treatment apparatus and a substrate treatment method that perform a heating process on a substrate prepared by coating a surface of the substrate with a resist and exposing the resist-coated substrate to light, a coating and developing apparatus including the substrate treatment apparatus, a coating and developing method including the substrate treatment method, and a storage medium.

2. Description of the Related Art

During a photoresist process that is one of semiconductor-manufacturing processes, a resist pattern is formed on semiconductor wafers (hereinafter, referred to simply as wafers) by coating the wafer surface with a resist and exposing the resist to light in the desired pattern, followed by development. Such a process is usually performed using a system that includes a coating and developing apparatus that performs a coating and development process and an exposure apparatus connected to the coating and developing apparatus.

The coating and developing apparatus has a heating module (post-exposure bake (PEB) module) that performs a heating process (post-exposure bake (PEB) process) on the exposed wafer. When the wafer is heated by the heating module, an acid generated from the resist by the exposure is thermally diffused. As a result, the exposed region of the wafer may be transformed and thereby the solubility of the exposed region in a developer may be changed.

The coating and developing apparatus includes a developing module that supplies a developer onto the wafer to develop the wafer after the heating process. The developing module performs a pre-wetting process to supply a surface treatment liquid onto the surface of the wafer W in order to improve the wettability of the wafer W with the developer. After the pre-wetting process, the developer is supplied onto the surface of the wafer W to form a liquid film. The liquid film is maintained for a predetermined time so that the resist is dissolved. After that, a cleaning liquid is supplied onto the wafer W to rinse the developer. In many cases, pure water or a developer is used as the surface treatment liquid. The developer used as the surface treatment liquid is used not for development but for improvement in wettability of the surface of the wafer with the developer supplied when a liquid film is formed.

Recently, an exposure apparatus that performs immersion exposure has been widely used. With this trend, a resist having a higher water-repellent property has been used in order to suppress an effect of a liquid used for immersion exposure. When such a resist having a high water-repellent property is to be developed, due to surface tension of the developer or pure water, the developer or pure water tends to gather on a region of the surface of the wafer having high wettability during the pre-wetting process and liquid film formation.

Specifically, when the pre-wetting process starts and the pure water spreads from a central region of the surface of the wafer to a peripheral edge portion of the surface of the wafer, wettability of a region of the surface of the wafer that is wet with the pure water is improved. However, wettability of a region of the surface of the wafer to which the pure water is not supplied is low. Once a region having high wettability is formed on the surface of the wafer, the pure water will move to the region having high wettability with the pure water due to the surface tension of the pure water even if the pure water is further supplied onto the surface of the wafer. Then, the pure water will pass through the region having high wettability with the pure water and fall out of a peripheral edge portion of the wafer. As a result, a region having low wettability with the pure water does not become wet with the pure water, with the pre-wetting process ending. Next, when the developer is supplied after termination of the pre-wetting process, the developer spreads to the region having high wettability. However, the developer does not spread to the region having low wettability due to the surface tension of the developer, as is the case with the pure water supplied in the pre-wetting process. Thus, the region having low wettability in question is not subjected to development process.

The size of the wafer tends to be increased in order to improve the throughput and a 450 mm diameter wafer is studied nowadays. When such a large wafer is used, the wafer may have many regions to which a developer is not applied, resulting in possibly development failure.

Instead of a process for supplying a developer onto the surface of a rotating wafer, the following developing method may be performed. A developer nozzle having a slit-like port, which extends across the diameter of a wafer, supplies a developer onto the surface of the wafer while moving from end to end of the wafer that is in a stationary state so that a liquid film made of the developer is formed on the wafer. After that, the wafer is kept stationary. However, when a resist is highly water-repellent, it may be difficult to uniformly form the liquid film for the aforementioned reasons even when this developing method is used.

In order to uniformly form a liquid film on the wafer, it is considered that the amount of the developer to be supplied onto the wafer is increased. This scheme, however, increases the time it takes for the development process, resulting in reduced throughput and high cost.

The developing module has nozzles placed at a predetermined position. One of the nozzles supplies a developer. Another one of the nozzles supplies a cleaning liquid. The other one of the nozzles supplies a surface treatment liquid. Since a driving mechanism moves each nozzle to the predetermined position, the driving mechanism may carry a large load. This may obstruct an improvement of the throughput of the coating and developing apparatus.

JP-A-2005-277268 describes a substrate treatment apparatus that supplies an atomized developer onto a substrate to develop the substrate and heats the substrate. The substrate treatment apparatus, however, does not include a mechanism that cools the heated substrate. Typically, an apparatus that performs the aforementioned PEB process needs to have such a cooling mechanism that cools the heated substrate, since it is necessary that the time for substrate heating be strictly monitored in order to control diffusion of an acid contained in a resist. The substrate treatment apparatus described in JP-A-2005-277268 is intended to heat the substrate after development and does not perform a PEB process. Thus, the substrate treatment apparatus described in JP-A-2005-277268 cannot solve the aforementioned problems.

### SUMMARY OF THE INVENTION

The present invention has been devised in order to solve the problems, and an object of the present invention is to provide a substrate treatment apparatus and a substrate treatment method, which are designed to heat an exposed substrate and capable of suppressing a development failure and a reduction in yield of wafers and reducing loads of processes that are performed by an apparatus located at the subsequent stage of the substrate treatment apparatus, and to provide a coating and developing apparatus, a coating and developing method and a storage medium.

According to an embodiment of the present invention, a substrate treatment apparatus includes:

a housing;

a heating plate that is located in the housing, the heating plate heating a substrate prepared by coating a surface of the substrate with a resist and exposing the resist-coated substrate to light;

means for atomizing a surface treatment liquid used to improve wettability of the substrate with a developer that is supplied onto the resist;

cooling means that is located in association with the heating plate, the cooling means cooling the substrate heated by the heating plate; and

surface treatment liquid supply means that is connected to the surface treatment liquid atomizing means, the surface treatment liquid supply means supplying the atomized surface treatment liquid onto the substrate for a portion of the period from the time when the heating plate starts heating the substrate until the cooling means terminates the cooling of the substrate.

According to an embodiment of the present invention, a substrate treatment apparatus includes:

a housing;

a heating plate that is located in the housing, the heating plate heating a substrate prepared by coating a surface of the substrate with a resist and exposing the resist-coated substrate to light;

means for atomizing a developer;

cooling means that is located in association with the heating plate, the cooling means cooling the substrate heated by the heating plate; and

developer supply means that is connected to the developer atomizing means, the developer supply means supplying the atomized developer onto the substrate for a portion of the period from the time when the heating plate starts heating the substrate until the cooling means terminates the cooling of the substrate

The substrate treatment apparatus may further include means for controlling the surface treatment liquid supply means such that the atomized surface treatment liquid is supplied onto the substrate during a portion of the period when the heating plate heats the substrate. The substrate treatment apparatus may be configured so that the heating plate also serves as a stage on which the substrate is mounted; the cooling means is a cooling plate capable of moving between an upper region defined above the heating plate and a region to which the cooling plate retreats from the upper region. The substrate treatment apparatus may be configured so that the cooling means cools the substrate in such a manner as to hold the substrate, locate the substrate in an upper region defined above the heating plate for heating, move the substrate between the upper region and a region to which the cooling means retreats from the upper region, and cause the heated substrate to retreat from the upper region.

According to an embodiment of the present invention, a substrate treatment method includes the steps of:

heating a substrate prepared by coating a surface of the substrate with a resist and exposing the resist-coated substrate to light;

atomizing a surface treatment liquid used to improve wettability of the substrate with a developer that is supplied onto the resist;

cooling the heated substrate by cooling means; and

supplying the atomized surface treatment liquid onto the substrate for a portion of the period from the time when the substrate is heated until the cooling means terminates the cooling of the substrate.

According to an embodiment of the present invention, a substrate treatment method includes the steps of:

heating a substrate prepared by coating a surface of the substrate with a resist and exposing the resist-coated substrate to light;

atomizing a developer;

cooling the heated substrate by cooling means; and

supplying the atomized developer onto the substrate for a portion of the period from the time when the substrate is heated until the cooling means terminates the cooling of the substrate.

The substrate treatment method may further include the step of supplying the atomized developer onto the substrate during the step of heating the substrate.

According to an embodiment of the present invention, a coating and developing apparatus includes:

a carrier block having a carrier capable of holding a plurality of substrates and transferring the substrates into and out of the carrier block;

a treatment block including a coating section that coats a resist on the surface of each substrate taken out of the carrier, a heating section that heats the resist-coated substrate subjected to an exposure process, a development section that supplies a developer onto the heated substrate to develop the substrate, and means for transferring the substrate among the coating section, the heating section, and the development section; and

an interface block that transfers the substrate between the treatment block and an exposure apparatus that exposes the resist to light;

wherein the heating section includes:
a housing;
a heating plate that is located in the housing, the heating plate heating the substrate prepared by coating the surface of the substrate with the resist and exposing the resist-coated substrate to light;
means for atomizing a surface treatment liquid used to improve wettability of the substrate with the developer that is supplied onto the resist;
cooling means that is located in association with the heating plate, the cooling means cooling the substrate heated by the heating plate; and
surface treatment liquid supply means that is connected to the surface treatment liquid atomizing means, the surface treatment liquid supply means supplying the atomized surface treatment liquid onto the substrate for a portion of the period from the time when the heating plate starts heating the substrate until the cooling means terminates the cooling of the substrate; and

wherein the treatment block includes a cleaning section that supplies a cleaning liquid onto the substrate supplied with the developer by the development section to remove the developer from the substrate.

According to an embodiment of the present invention, a coating and developing apparatus includes:

a carrier block having a carrier capable of holding a plurality of substrates and transferring the substrates into and out of the carrier block;

a treatment block including a coating section that coats a resist on the surface of each substrate taken out of the carrier, a heating section that heats the resist-coated substrate subjected to an exposure process, a cleaning section that supplies a cleaning liquid to the substrate supplied with the developer to remove the developer from the substrate, and means for transferring the substrate among the coating section, the heating section, and the cleaning section; and

an interface block that transfers the substrate between the treatment block and an exposure apparatus that exposes the resist to light;

wherein the heating section includes:
a housing;
a heating plate that is located in the housing, the heating plate heating the substrate prepared by coating the surface of the substrate with the resist and exposing the resist-coated substrate to light;
means for atomizing the developer;
cooling means that is located in association with the heating plate, the cooling means cooling the substrate heated by the heating plate; and
developer supply means that is connected to the developer atomizing means, the developer supply means supplying the atomized developer onto the substrate for a portion of the period from the time when the heating plate starts heating the substrate until the cooling means terminates the cooling of the substrate.

The coating and developing apparatus may alternately repeat a process for supplying the atomized developer onto the substrate by means of the heating section and a process for supplying the cleaning liquid onto the substrate by means of the cleaning section.

According to an embodiment of the present invention, a coating and developing method uses a coating and developing apparatus. The apparatus comprises:

a carrier block having a carrier capable of holding a plurality of substrates and transferring the substrates into and out of the carrier block;

a treatment block including a coating section that coats a resist on the surface of each substrate taken out of the carrier, a heating section that heats the resist-coated substrate subjected to an exposure process, a development section that supplies a developer onto the heated substrate to develop the substrate, and means for transferring the substrate among the coating section, the heating section, and the development section; and

an interface block that transfers the substrate between the treatment block and an exposure apparatus that exposes the resist to light;

the coating and developing method comprising the steps of:

heating the substrate prepared by coating the surface of the substrate with the resist and exposing the resist-coated substrate to light;

atomizing a surface treatment liquid used to improve wettability of the substrate with the developer that is supplied onto the resist;

cooling the heated substrate by cooling means;

supplying the atomized surface treatment liquid onto the substrate for a portion of the period from the time when the substrate is heated until the cooling means terminates the cooling of the substrate; and

supplying a cleaning liquid onto the substrate supplied with the developer by the development section to remove the developer from the substrate.

According to an embodiment of the present invention, a coating and developing method uses a coating and developing apparatus. The apparatus comprises:

a carrier block having a carrier capable of holding a plurality of substrates and transferring the substrates into and out of the carrier block;

a treatment block including a coating section that coats a resist on the surface of each substrate taken out of the carrier, a heating section that heats the resist-coated substrate subjected to an exposure process, a cleaning section that supplies a cleaning liquid onto the substrate supplied with a developer to remove the developer from the substrate, and means for transferring the substrate among the coating section, the heating section, and the cleaning section; and

an interface block that transfers the substrate between the treatment block and an exposure apparatus that exposes the resist to light;

the coating and developing method comprising the steps of:

heating the substrate prepared by coating the surface of the substrate with the resist and exposing the resist-coated substrate to light;

atomizing the developer;

cooling the heated substrate by cooling means; and

supplying the atomized developer onto the substrate for a portion of the period from the time when the substrate is heated until the cooling means terminates the cooling of the substrate.

In the coating and developing method, the step of supplying the atomized developer onto the substrate and the step of supplying the cleaning liquid onto the substrate can be alternately repeated.

According to an embodiment of the present invention, a storage medium stores a computer program that is used for a substrate treatment apparatus that heats a substrate. The computer program is designed to perform a substrate treatment method, the method including the steps of:

heating the substrate prepared by coating the surface of the substrate with a resist and exposing the resist-coated substrate to light;

atomizing a surface treatment liquid used to improve wettability of the substrate with a developer that is supplied onto the resist;

cooling the heated substrate by cooling means; and

supplying the atomized surface treatment liquid onto the substrate for a portion of the period from the time when the substrate is heated until the cooling means terminates the cooling of the substrate.

According to an embodiment of the present invention, a storage medium stores a computer program that is used for a substrate treatment apparatus that heats a substrate. The computer program is designed to perform a substrate treatment method, the method including the steps of:

heating the substrate prepared by coating the surface of the substrate with a resist and exposing the resist-coated substrate to light;

atomizing a developer;

cooling the heated substrate by cooling means; and

supplying the atomized developer onto the substrate for a portion of the period from the time when the substrate is heated until the cooling means terminates the cooling of the substrate.

The substrate treatment apparatus includes: the means for atomizing the surface treatment liquid used to improve wettability of the substrate with a developer; and the surface treatment liquid supply means for supplying the atomized surface treatment liquid onto the substrate for a portion of the period from the time when the heating plate starts heating the substrate until the cooling means terminates the cooling of the substrate. The surface tension of the atomized surface treatment liquid with respect to the substrate is lower than the surface tension of the surface treatment liquid (that is in the form of a liquid) with respect to the substrate. The atomization suppresses the fact that the surface treatment liquid gathers on a certain portion of the surface of the substrate. Thus, the surface treatment liquid can be easily supplied onto the entire surface of the substrate, and the wettability can be improved. As a result, an apparatus located at the subsequent stage of the substrate treatment apparatus can supply a developer onto the substrate in a highly uniform manner. Therefore, a development failure can be suppressed, and a reduction in yield of wafers can be suppressed.

The substrate treatment apparatus includes: the means for atomizing the developer; and the developer supply means for supplying the atomized developer onto the substrate for a portion of the period from the time when the heating plate starts heating the substrate until the cooling means terminates the cooling of the substrate. The atomized developer can be easily supplied onto the entire surface of the substrate for the same reason as the atomized surface treatment liquid. Thus, a development failure can be suppressed, and a reduction in yield of wafers can be suppressed.

### BRIEF DESCRIPTION OF THE DRAWINGS

FIG. 1 is a vertical cross sectional view of a heating apparatus according to an embodiment of the present invention.

FIG. 2 is a plan view of the heating apparatus.

FIG. 3 is a vertical cross sectional view of the configuration of a treatment container included in the heating apparatus.

FIGS. 4A to 4C are diagrams showing procedures of a process performed in the heating apparatus.

FIG. 5 is a diagram showing procedures of a process performed in the heating apparatus.

FIGS. 6A and 6B are vertical and horizontal cross sectional views of another configuration of the heating apparatus.

FIGS. 7A and 7B are plan and side views of another outline configuration of the heating apparatus.

FIG. 8 is a plan view of a coating and developing apparatus including the heating apparatus.

FIG. 9 is a perspective view of the coating and developing apparatus including the heating apparatus.

FIG. 10 is a vertical cross sectional view of the coating and developing apparatus.

FIG. 11 is a perspective view of a transfer region included in the coating and developing apparatus.

FIG. 12 is an outline diagram showing a developing module included in the coating and developing apparatus.

FIGS. 13A to 13C are flowcharts of processes performed by the coating and developing apparatus.

FIGS. 14A to 14C are schematic diagrams showing changes in the surface of a wafer.

### DESCRIPTION OF THE PREFERRED EMBODIMENTS

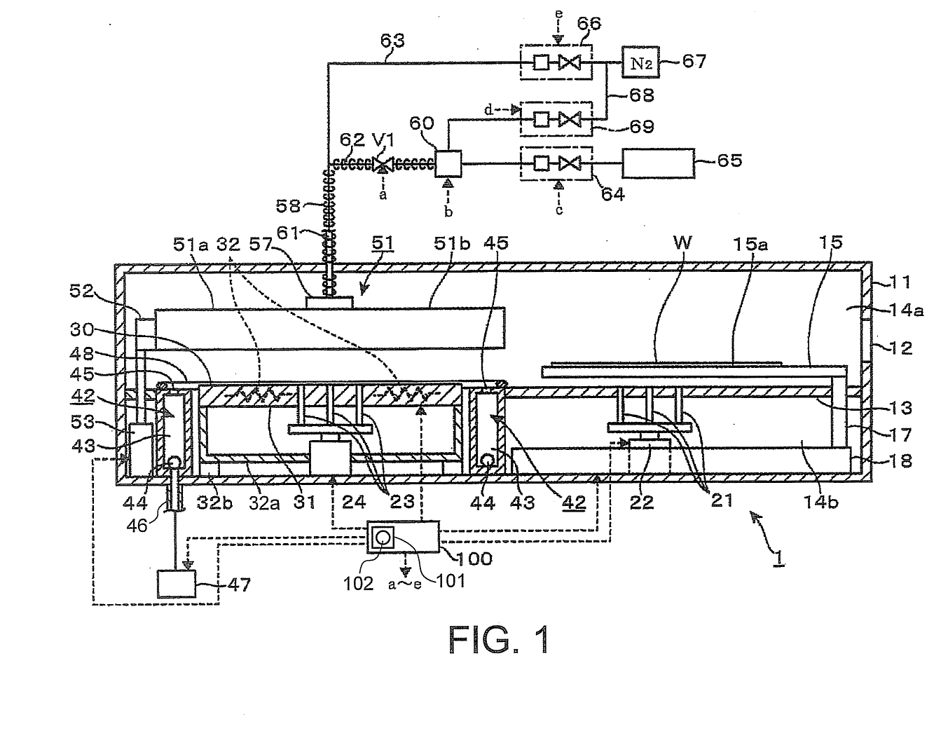

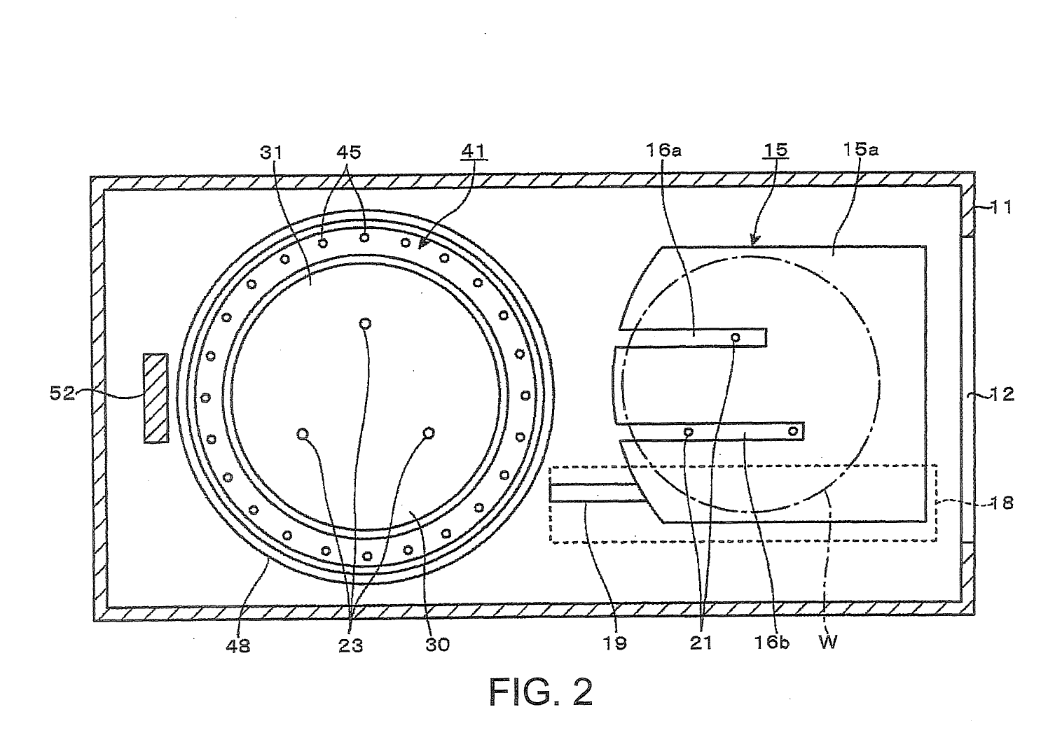

A heating apparatus 1 that is an example of a substrate treatment apparatus according to the present invention is described below with reference to FIGS. 1 and 2. FIG. 1 is a vertical cross sectional view of the heating apparatus 1. FIG. 2 is a horizontal cross sectional view of the heating apparatus 1. The heating apparatus 1 performs the PEB process (described in the Background of the Art) on a wafer W prepared by coating a surface of the wafer with a resist and exposing the resist-coated wafer to light. The heating apparatus 1 then supplies an atomized developer onto the wafer W. A developing apparatus located at the subsequent stage of the heating apparatus 1 performs a pre-wetting process to improve wettability of the wafer with the developer when the developer is supplied onto the wafer W. Alternatively, the developing apparatus performs a development process on the wafer W by means of the atomized developer. The resist has a water-repellent property and is subjected to an exposure process using a predetermined pattern. An exposed region of the resist has solubility in the developer. A static contact angle of the resist with respect to water is, for example, 80 degrees or more. The diameter of the wafer W is in a range of 300 mm to 450 mm, for example.

The heating apparatus 1 has a housing 11. The housing 11 has a transfer port 12 (that is an opening) in a wall of the housing 11. The wafer W is transferred from the outside of the housing 11 into the housing 11 through the transfer port 12 by a substrate transfer unit (not shown). The housing 11 includes a partition plate 13 that partitions an inner space of the housing 11 into an upper inner space and a lower inner space. The upper inner space of the housing 11 is defined as a transfer region 14a formed to transfer the wafer W to a heating plate 31. A horizontally-oriented cooling plate 15 is located in the transfer region 14a and on the side of the transfer port 12. The cooling plate 15 is located in association with the heating plate 31.

The cooling plate 15 has a cooling flow passage (not shown) in which water for temperature adjustment or the like flows. The cooling flow passage is located on the side of a back surface of the cooling plate 15. When the wafer W heated by the heating plate 31 is placed on a front surface 15a of the cooling plate 15, the wafer W is cooled by the cooling plate 15. In FIG. 2, reference numerals 16a and 16b denote slits formed in the cooling plate 15.

The cooling plate 15 cools the wafer W placed on the cooling plate 15 and also serves as a transfer unit to transfer the wafer W to the heating plate 31. The cooling plate 15 is connected to a driving section 18 through a support member 17. The driving section 18 is located in the lower inner space 14b of the housing 11. The driving section 18 drives the cooling plate 15 to cause the cooling plate 15 to horizontally move from the side of the transfer port 12 to the opposite side to the side of the transfer port 12 in the housing 11. The driving section 18 includes a speed controller (not shown), for example. The speed controller allows the cooling plate 15 to move at speed based on a control signal output from a controller 100. In FIG. 2, reference numeral 19 denotes a slit formed in the partition plate 13. The support member 17 extends through the slit 19.

In FIG. 2, reference numeral 21 denotes three lifting pins. The lifting pins 21 are moved up and down by a lifting mechanism 22 through the slits 16a and 16b of the cooling plate 15 that moves to the side of the transfer port 12 and is located on the side of the transfer port 12. The lifting pins 21 transfer the wafer W between the cooling plate 15 and the substrate transfer unit located in the housing 11 after the substrate transfer unit enters through the transfer port 12.

The heating plate 31 is located on the opposite side to the side of the transfer port 12. The wafer W is placed on the heating plate 31 and heated by the heating plate 31. The heating plate 31 has a heater 32 therein. When the heater 32 receives a control signal from the controller 100, the heater 32 controls the temperature of a front surface 30 (on which the wafer W is placed) of the heating plate 31 and heats the wafer W placed on the front surface 30 of the heating plate 31 to a certain temperature. In FIG. 1, reference numerals 32a and 32b denote support members. The support members 32a and 32b hold the heating plate 31 so that the heating plate 31 is horizontally oriented. In FIG. 1, reference numeral 23 denotes three lifting pins. The lifting pins 23 are moved up and down through the slits 16 (of the cooling plate 15 located above the heating plate 31) by a lifting mechanism 24. The lifting pins 23 transfer the wafer W between the cooling plate 15 and the heating plate 31.

A ring-shaped discharge section 41 surrounds the heating plate 31 and has a discharge space 42 therein. A partition member 43 is located in the discharge space 42 and partitions the discharge space 42 into spaces in a circumferential direction of the discharge section 41. The spaces partitioned by the partition member 43 communicate with each other through a communication port 44 provided in the partition member 43. A plurality of discharge ports 45 are provided in the surface of the discharge section 41 and arranged in the circumferential direction of the discharge section 41. The plurality of discharge ports 45 communicate with the discharge space 42.

The discharge section 41 is connected to an end of a discharge pipe 46. The other end of the discharge pipe 46 is connected to a discharge unit 47 that includes a vacuum pump. The discharge unit 47 discharges a gas from the discharge port 45 through the discharge pipe 46, the communication port 44, and the discharge space 42. The discharge unit 47 includes a pressure control unit (not shown). When the pressure control unit receives a control signal from the controller 100, the pressure control unit controls the amount of the gas (that is to be discharged) on the basis of the received control signal.

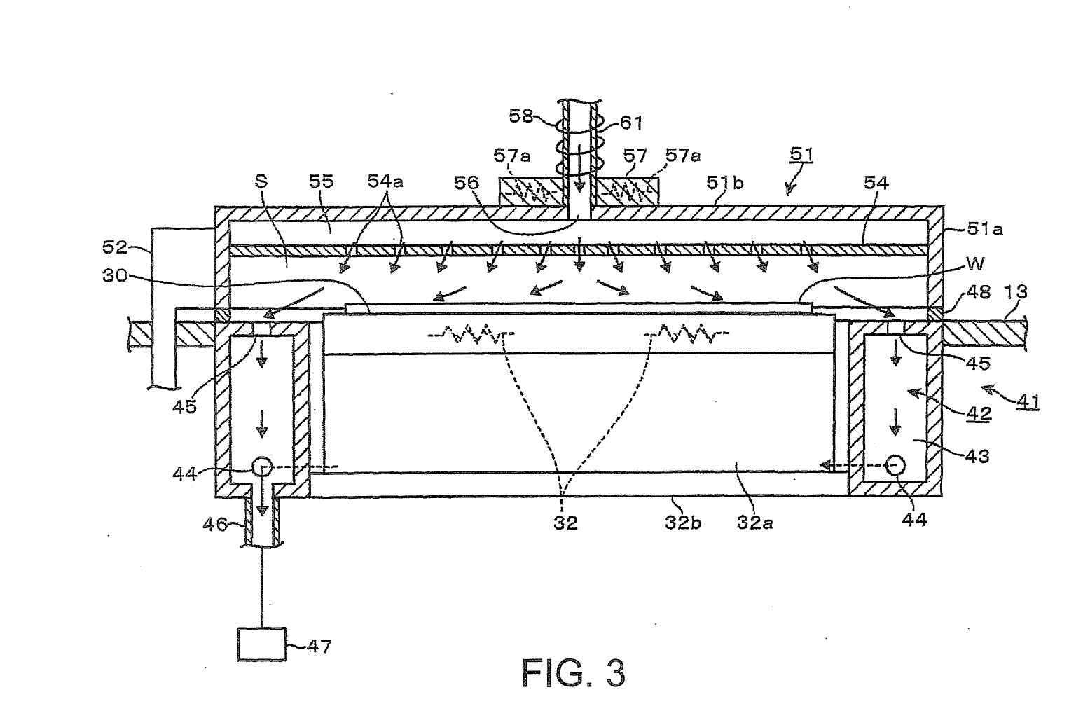

A circular lid body 51 is provided above the heating plate 31 and can be moved up and down by a lifting mechanism 53 through a support member 52. The lid body 51 has an edge portion 51a extending downward and is formed in a cup-like shape. Referring to FIG. 3, when the lid body 51 moves down, the edge portion 51a is fitted to an edge portion of the discharge section 41 through a ring-shaped fitting member 48. A space surrounding the wafer W placed on the heating plate 31 is sealed and forms a treatment space S.

As shown in FIG. 3, the lid body 51 includes a horizontally-oriented flow adjusting plate 54 surrounded by the edge portion 51a. In addition, the lid body 51 has a top plate 51b. A ventilating space 55 is formed between the flow adjusting plate 54 and the top plate 51b. The flow adjusting plate 54 has many outlet ports 54a in order to uniformly supply the atomized developer onto the wafer W. Each of the outlet ports 54a vertically extends between the ventilating space 55 and the treatment space S. The lid body 51 has an opening portion 56 located at a central portion of the lid body 51. The opening portion 56 is connected to an end of a gas supply pipe 61 (surface treatment liquid supply unit).

As shown in FIG. 1, the gas supply pipe 61 is branched into gas supply pipes 62 and 63 on the upstream side of the gas supply pipe 61. An end of the gas supply pipe 62 is connected to a developer supply source 65 through a valve V1, an atomizing section 60 (surface treatment liquid atomizing unit), and a flow rate controller 64, in that order. The developer supply source 65 stores the developer. An end of the gas supply pipe 63 is connected to an N₂ gas supply source 67 through a flow rate controller 66. The N₂ gas supply source 67 stores an inert gas such as an N₂ gas. The lid body 51 has a heating section 57 located on the upper central portion of the lid body 51. The heating section 57 includes a heater 57a. A tape heater 58 is wound around a portion (located on the downstream side of the atomizing section 60) of the gas supply pipe 62 and around the gas supply pipe 61. Before the atomized developer is supplied into the treatment space S, the heating section 57 heats the lid body 51 to a predetermined temperature, and the tape heater 58 heats the gas supply pipes 61 and 62 to a predetermined temperature. The heating by the heating section 57 and the tape heater 58 prevents the developer from being re-liquefied.

The atomizing section 60 is connected to an end of the gas supply pipe 68. The other end of the gas supply pipe 68 is connected to the gas supply pipe 63 through a flow rate controller 69 on the upstream side of the flow rate controller 66. Each of the flow rate controllers 64, 66, and 69 includes a valve or a mass flow controller. The flow rate controller 64 controls, on the basis of a control signal output from the controller 100, the flow rate of the developer that flows on the downstream side. Each of the flow rate controllers 66 and 69 controls, on the basis of a control signal output from the controller 100, the flow rate of the N₂ gas that flows on the downstream side. Opening and closing of the valve V1 is controlled by a control signal output from the controller 100.

The atomizing section 60 includes a tank and an oscillator. The tank stores the developer supplied from the developer supply source 65. The oscillator applies, on the basis of a control signal output from the controller 100, an ultrasonic wave to the developer stored in the tank to generate an atomized developer. The diameter of a particle of the atomized developer is 3 μm or less, for example. The N₂ gas (carrier gas) supplied to the atomizing section 60 causes the atomized developer generated by the atomizing section 60 to flow through the gas supply pipes 61 and 62. The atomized developer and the N₂ gas are then supplied to the wafer W.

Next, the controller 100 is described below. The controller 100 includes a computer and a program storage section 101. The program storage section 101 stores a program (such as software) including instructions that are to be used to perform a development process (described later). The controller 100 reads the program to control the temperature of the heating plate 31, the movement of the cooling plate 15, the vertical movement of the lid body 51, the supply of the N₂ gas, the supply of the atomized developer and the like. The program storage section 101 has a storage medium 102 (such as a hard disk, a compact disc, a magnet optical disk, a memory card or the like). The program is stored in the storage medium 102.

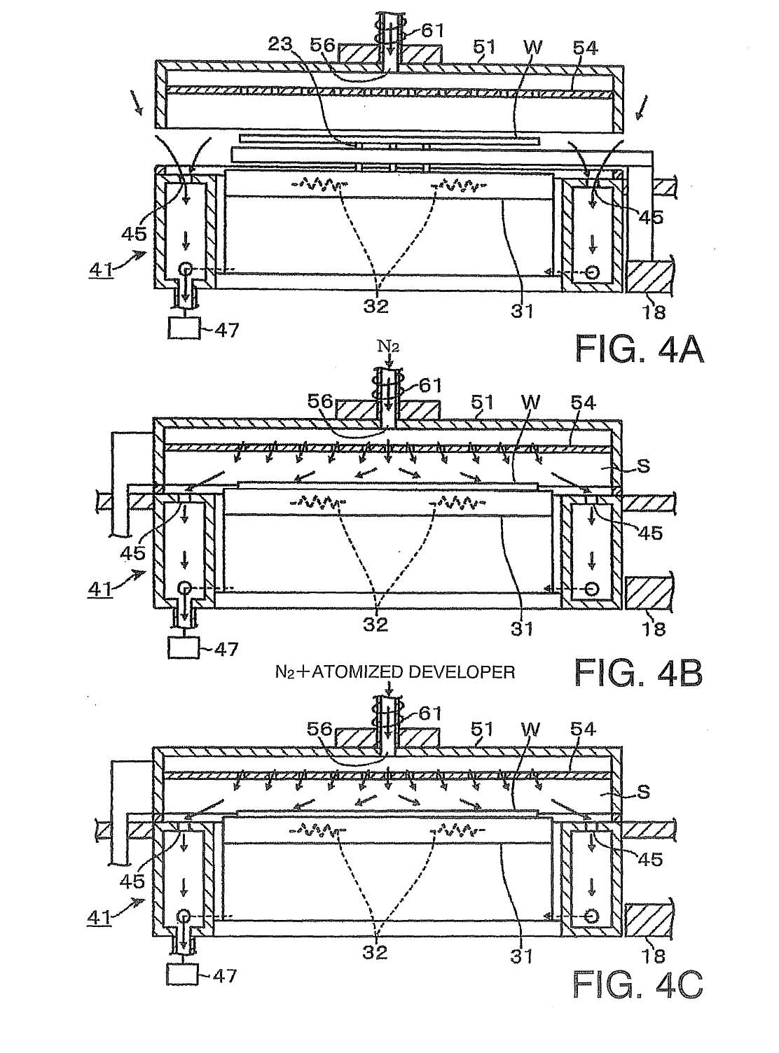

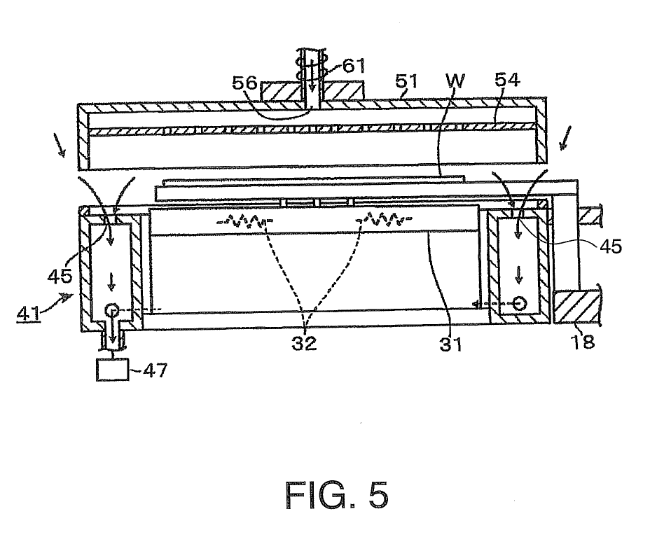

After the heating apparatus 1 performs the PEB process on the wafer W, the pre-wetting process is performed. The pre-wetting process is described below with reference to FIGS. 4A, 4B, 4C and 5.

(Step S1: Transfer of Wafer W into Heating Apparatus)

After the wafer W is transferred into the heating apparatus 1 by the substrate transfer unit (not shown), the wafer W is placed on the front surface 15a of the cooling plate 15 by a cooperative operation of both the substrate transfer unit and the lifting pins 21. In this case, the lid body 51 is located at an upper position shown in FIG. 1. The discharge unit 47 discharges a gas included in the housing 11 at a predetermined discharge rate. Particles included in the housing 11 flow with the flow of the gas and are removed from the housing 11.

The cooling plate 15 having the wafer W placed thereon moves and is positioned above the heating plate 31. The lifting pins 23 protrude from the front surface of the cooling plate 15 and hold a back surface of the wafer W (as shown in FIG. 4A). When the cooling plate 15 moves toward the transfer port 12 from the position at which the cooling plate 15 is located above the heating plate 31, the lifting pins 23 move down so that the wafer W is placed on the heating plate 31, and the lid body 51 moves down to form the sealed treatment space S.

### (Step S2: Heating of Wafer W)

The temperature of the heating plate 31 is increased to a range of 100 degrees C. to 120 degrees C., and whereby the temperature of the wafer W increases to a range of 100 degrees C. to 120 degrees C. In addition, the N₂ gas is supplied into the treatment space S through the gas supply pipes 63 and 61. Then, the N₂ gas is removed from the treatment space S through the discharge port 45 of the discharge section 41 and flows as shown by arrows in FIG. 4B. The wafer W is then subjected to the heating process for a predetermined time while being exposed to the flow of the N₂ gas. Sublimate produced from the wafer W by the heating flows with the flow of the N₂ gas and is removed from the treatment space S.

### (Step S3: Pre-Wetting Process)

After the wafer W is heated for the predetermined time, the temperature of the heating plate 31 is reduced to a range of 20 degrees C. to 40 degrees C., and the rate of discharging the gas from the treatment space S by means of the discharge unit 47 is reduced. Then, the atomizing section 60 atomizes the developer to generate an atomized developer. The supply of the N₂ gas to the gas supply pipe 63 is stopped. The N₂ gas is supplied to the atomizing section 60. The N₂ gas pushes the atomized developer toward the downstream side so that the atomized developer flows toward the downstream side. Then, the valve V1 is open to supply the N₂ gas and the atomized developer into the treatment space S (as shown in FIG. 4C). The atomized developer supplied onto the wafer W is in the form of mist or in the form of particles. The surface tension of the atomized developer with respect to the resist is lower than the surface tension of the developer (that is in the form of a liquid) with respect to the resist. The atomization suppresses the fact that the developer gathers on a certain portion (of the resist formed on a front surface of the wafer) on which the developer has high wettability. Thus, the atomized developer is supplied onto the entire surface of the wafer W in a highly uniform manner. As a result, the wettability of the entire surface of the wafer W with the developer is improved.

### (Step S4: Cooling of Wafer W and Transfer of Wafer W to Outside of Heating Apparatus)

After a predetermined time elapses from the start of the supply of the atomized developer, the valve V1 is closed and the supply of the N₂ gas to the atomizing section 60 is stopped so that the supply of the atomized developer onto the wafer W is stopped. The discharge rate of the discharge unit 47 is increased to, for example, the discharge rate set for the step S1 or a discharge rate set for the step 2. After that, the lid body 51 and the lifting pins 23 move up so that the wafer W is held by the lifting pins 23 and separated from the heating plate 31. Then, the cooling plate 15 moves and is positioned above the heating plate 31 and under the wafer W. Then, the lifting pins 23 moves down so that the wafer W is placed on the cooling plate 15 and cooled by the cooling plate 15 (as shown in FIG. 5). After that, the cooling plate 15 moves toward the transfer port 12, and the wafer W is transferred to the substrate transfer unit by the lifting pins 21. Then, the wafer W is transferred to the outside of the housing 11. The wafer W is then transferred to the developing apparatus, and the developer is supplied onto the surface (of the wafer W) subjected to the pre-wetting process. The developer is then rinsed so that a resist pattern is formed on the wafer W.

The heating apparatus 1 includes the atomizing section 60 that atomizes the developer that is used for the pre-wetting process in order to improve the wettability of the wafer W with the developer. The surface tension of the atomized developer with respect to the wafer W is lower than the surface tension of the developer (that is in the form of a liquid) with respect to the wafer W. The atomization suppresses the fact that the developer gathers on a certain portion of the wafer W. Thus, the developer can be easily supplied onto the entire surface of the wafer W, and the wettability of the wafer W with the developer can be improved. The developer can be supplied onto the wafer W in a highly uniform manner. As a result, the atomization suppresses generation of an abnormally developed portion and suppresses a reduction in yield of wafers. In addition, it is not necessary that the developing apparatus located at the subsequent stage of the heating apparatus 1 performs the pre-wetting process. Thus, a nozzle included in the developing apparatus does not need to move. A load caused by a process performed by the developing apparatus can be reduced. As a result, the throughput of the developing apparatus can be improved.

It is not necessary that the heating apparatus 1 have the flow adjusting plate 54. When the heating apparatus 1 does not have the flow adjusting plate 54, the atomized developer may be supplied onto the wafer W directly from the opening portion 56. In this example, the developer is used as the surface treatment liquid atomized for the pre-wetting process. The surface treatment liquid is not limited to the developer. Pure water or a mixed liquid containing pure water and the developer may be used as the surface treatment liquid. The atomized pure water or the atomized mixed liquid may be supplied onto the wafer W.

In the step S3, the pre-wetting process using the atomized developer is performed on the wafer W. Instead of the pre-wetting process, a development process may be performed so that a sufficient amount of the atomized developer is supplied onto the wafer W to form a liquid film of the developer on the surface of the wafer W. In this case, the wafer W is transferred to a cleaning apparatus after the process performed by the heating apparatus 1. Then, the cleaning apparatus supplies a cleaning liquid onto the wafer W to remove the developer from the surface of the wafer W. In this case, since a process by an apparatus located at the subsequent stage of the heating apparatus 1 is simplified, the same effects as described in the aforementioned embodiment can be obtained. During the development process by the heating apparatus 1, the atomized developer and the resist efficiently chemically react with each other to develop the wafer W. Thus, the wafer W is heated to a range of 30 degrees C. to 60 degrees C. during the supply of the atomized developer.

According to the procedures of the processes, the atomized developer is supplied after the PEB process. The atomized developer, however, may be supplied during the PEB process. The PEB process and the pre-wetting process may be simultaneously performed. Alternatively, the PEB process and the development process may be simultaneously performed.

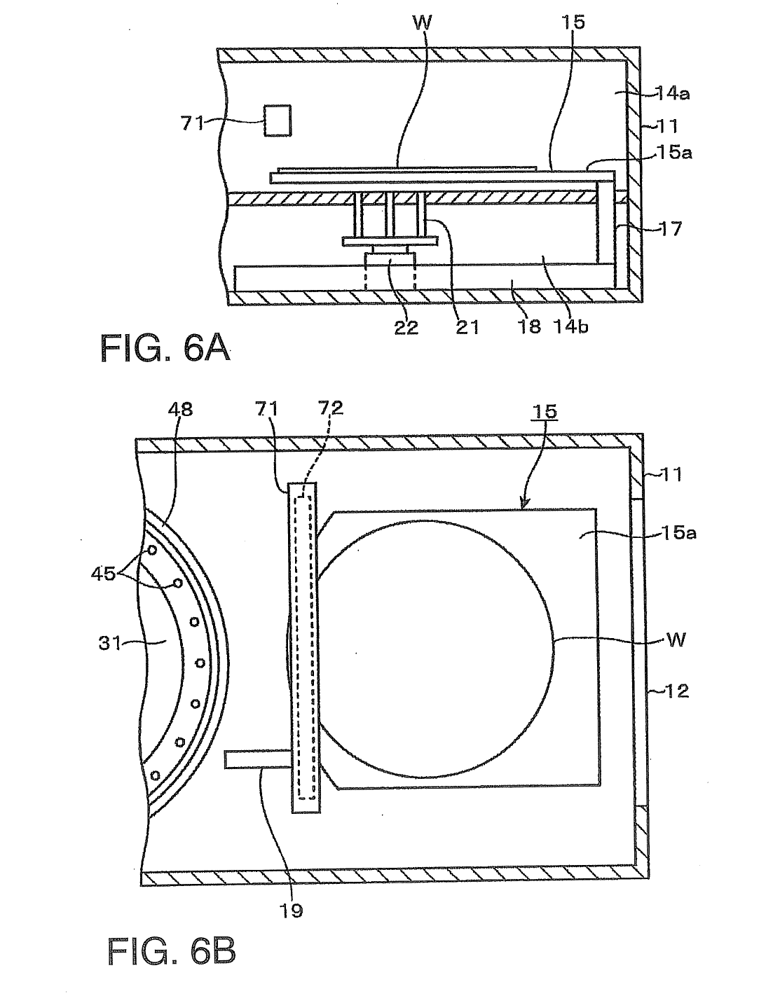

Instead of the operation for supplying the atomized developer into the treatment space S formed by the lid body 51, a spray nozzle 71 that sprays the atomized developer may be provided on a route along which the cooling plate 15 moves as shown in FIGS. 6A and 6B. In this case, the spray nozzle 71 supplies the atomized developer onto the entire surface of the wafer W during the cooling of the wafer W (subjected to the heating process) by the cooling plate 15 and during the movement of the wafer W toward the transfer port 12. In FIG. 6B, reference numeral 72 denotes an outlet of the spray nozzle 71. The outlet 72 of the spray nozzle 71 is open downward and formed in a slit shape to allow the atomized developer to be supplied onto the entire surface of the wafer W.

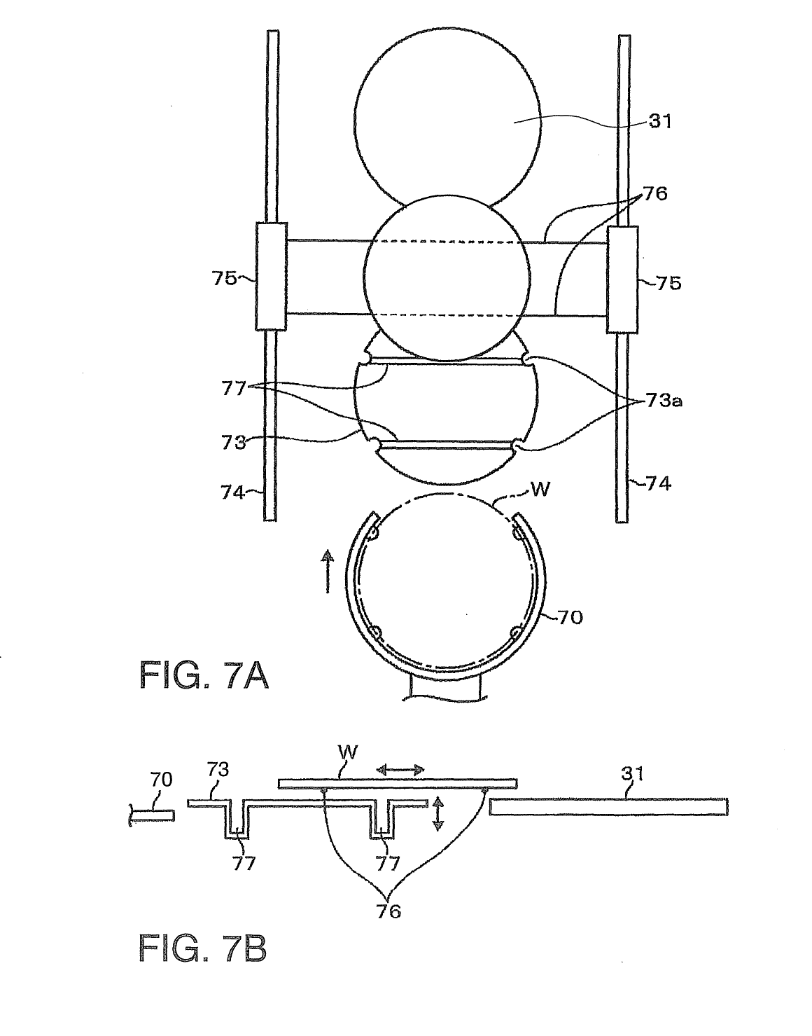

In the aforementioned example, the heating apparatus has the cooling plate 15 that moves between the two locations and is positioned above the heating plate 31 at one of the two locations and positioned separately from the heating plate 31 at the other location. The heating apparatus, however, may have a configuration shown in FIGS. 7A and 7B. FIG. 7A is a plan view of the heating apparatus, and FIG. 7B is a side view of the heating apparatus. In FIGS. 7A and 7B, the mechanism for supplying the atomized developer and the discharge mechanism are not illustrated, since the mechanisms included in the heating apparatus shown in FIGS. 7A and 7B are the same as those included in the aforementioned heating apparatus 1. In FIGS. 7A and 7B, reference numeral 73 denotes a cooling plate. The cooling plate 73 has a cooling mechanism (not shown) in a back surface of the cooling plate 73. The cooling mechanism of the cooling plate 73 causes water for temperature adjustment to flow to cool the wafer W placed on the cooling plate 73 as is the case with the cooling plate 15. The cooling plate 73 is capable of moving up and down. The vertical movement of the cooling plate 73 allows the wafer W to be transferred between the cooling plate 73 and a substrate transfer unit 70. Thus, the cooling plate 73 has a cutout 73a formed on the basis of the shape of the substrate transfer unit 70.

Reference numeral 74 denotes guide rails. One of the guide rails 74 extends from the right side of the cooling plate 73 toward the heating plate 31, and the other of the guide rails 74 extends from the left side of the cooling plate 73 toward the heating plate 31. Reference numeral 75 denotes movable mechanisms that move along the respective guide rails 74. A wire 76 is stretched between the movable mechanisms 75. The movable mechanisms 75 and the wire 76 form a holding mechanism that holds the wafer W.

The substrate transfer unit 70 transfers the wafer W to the heating apparatus. When the substrate transfer unit 70 is located above the cooling plate 73 while holding the wafer W, the wire 76 is located in a groove 77 formed in the cooling plate 73. After that, the cooling plate 73 moves up and receives the wafer W from the substrate transfer unit 70. Then, the cooling plate 73 moves down and transfers the wafer W to the wire 76. After that, the wafer W is transferred to the heating plate 31 by the wire 76. The wafer W is then placed on the heating plate and heated by the heating plate 31. The atomized developer is supplied onto the wafer W. After the supply of the atomized developer, the wafer W moves toward the cooling plate 73 and is naturally cooled during the movement of the wafer W. When the wafer W is positioned above the cooling plate 73, the cooling plate 73 moves up, and the wafer W is transferred to the cooling plate 73 and further cooled by the cooling plate 73.

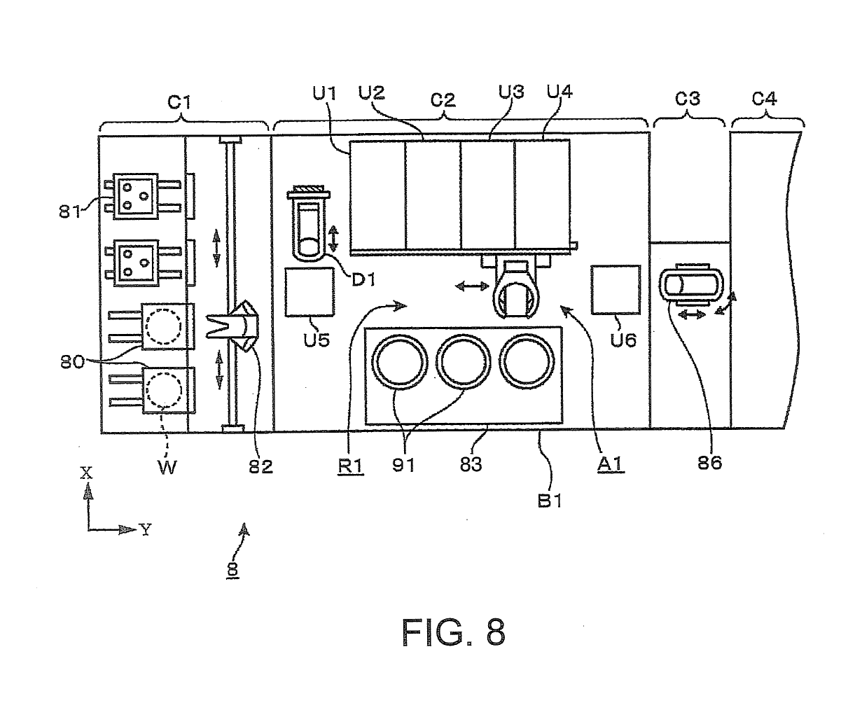

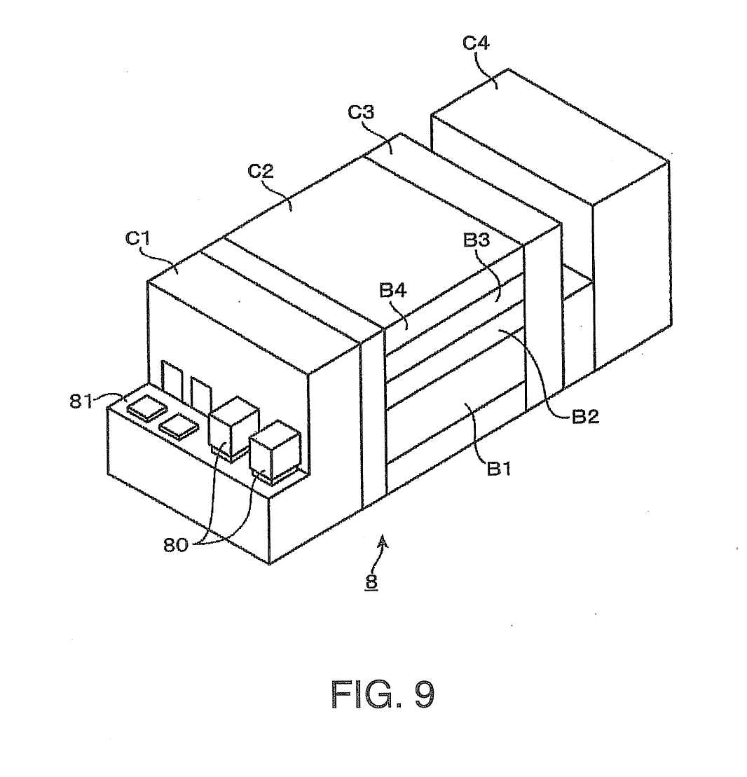

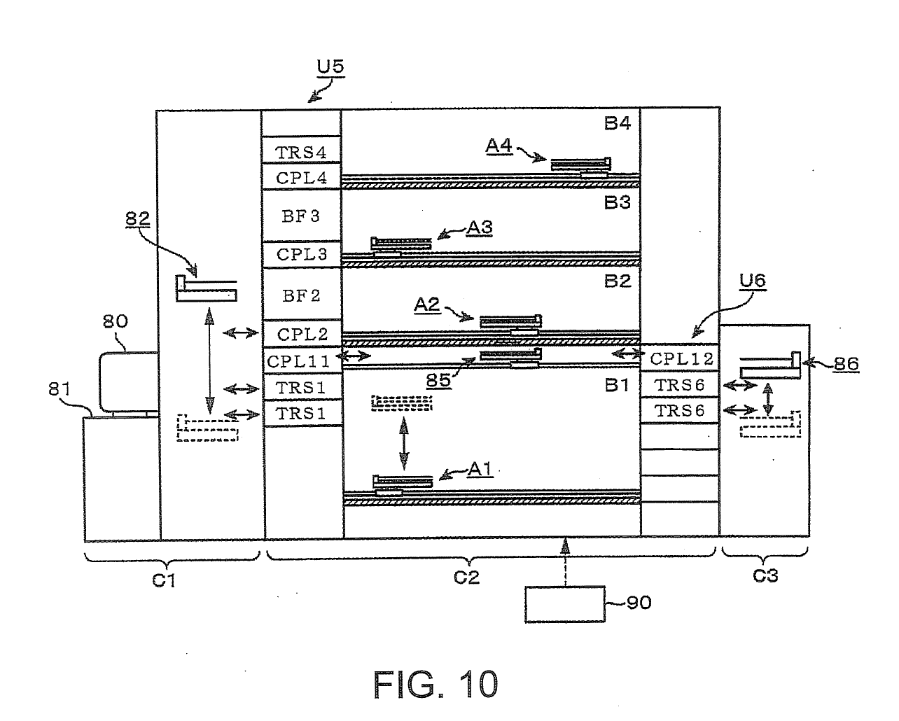

Next, a coating and developing apparatus 8 including the heating apparatus 1 as a module is described below. FIG. 8 is a plan view of a resist pattern formation system that includes the coating and developing apparatus 8 and an exposure apparatus C4. The exposure apparatus C4 is connected to the coating and developing apparatus 8 and performs, for example, immersion exposure. FIG. 9 is a perspective view of the resist pattern formation system. FIG. 10 is a vertical cross sectional view of the coating and developing apparatus 8.

The coating and developing apparatus 8 has a controller 90. The controller 90 includes a computer and has a configuration similar to that of the controller 100. The controller 90 has a program storage section storing a program that includes instructions in order to perform coating and development processes. The controller 90 outputs a control signal in accordance with the program and controls transfer of the wafer W, operations of modules and the like. The program storage section included in the controller 90 has a storage medium. The program is stored in the storage medium included in the controller 90.

The coating and developing apparatus 8 has a carrier block C1. The carrier block C1 has a stage 81, a sealed type carrier 80, and a transfer arm 82. The carrier 80 is placed on the stage 81. The transfer arm 82 receives the wafer W from the sealed type carrier 80 and transfers the wafer W to a treatment block C2. The wafer W is treated in the treatment block C2. The transfer arm 82 receives the treated wafer W from the treatment block C2 and returns the wafer W to the carrier 80. The carrier 80 is capable of holding a plurality of wafers W. The wafers W are sequentially transferred to the treatment block C2.

As shown in an example illustrated in FIG. 9, the treatment block C2 has a first block (DEV layer) B1, a second block (BCT layer) B2, a third block (COT layer) B3, and a fourth block (ITC layer) B4 laminated in this order from the bottom of the treatment block C2. The first block (DEV layer) B1 performs a development process. The second block (BCT layer) B2 performs a process for forming an antireflective film under a resist film. The third block (COT layer) B3 coats the resist film on the wafer W. The fourth block (ITC layer) B4 forms a protective film on or above the resist film.

Each of the layers included in the treatment block C2 is configured in a similar way to the first block B1 shown in the plan view of FIG. 8. The third block (COT layer) B3 is explained as an example. The third block (COT layer) B3 includes a resist film formation module, shelf units U1 to U4, and a transfer arm A3. The resist film formation module included in the third block B3 forms a resist film as a coated film. The shelf units U1 to U4 included in the third block B3 form a heating/cooling treatment module group that performs processes before and after the formation process performed by the resist film formation module. The transfer arm A3 is located between the resist film formation module and the heating/cooling treatment module group and transfers the wafer W between the resist film formation module and the heating/cooling treatment module group.

The shelf units U1 to U4 included in the third block B3 are arranged along a transfer region R1 in which the transfer arm A3 moves. Each of the shelf units U1 to U4 includes a heating module and a cooling module, which are laminated. Each heating module includes a heating plate that heats the wafer W placed on the heating plate. Each cooling module includes a cooling plate that cools the wafer W placed on the cooling plate.

Each of the second blocks (BCT layers) B2 and the fourth blocks (ITC layers) B4 has an antireflective film formation module and a protective film formation module, which correspond to the resist film formation module. Each antireflective film formation module supplies a chemical liquid (for formation of the antireflective film) onto the wafer W as a treatment liquid instead of the resist. Each protective film formation module supplies a chemical liquid (for formation of the protective film) onto the wafer W as a treatment liquid instead of the resist. Other configurations of each of the second blocks (BCT layers) B2 and the fourth blocks (ITC layers) B4 are the same as those of each third block (COT layer) B3.

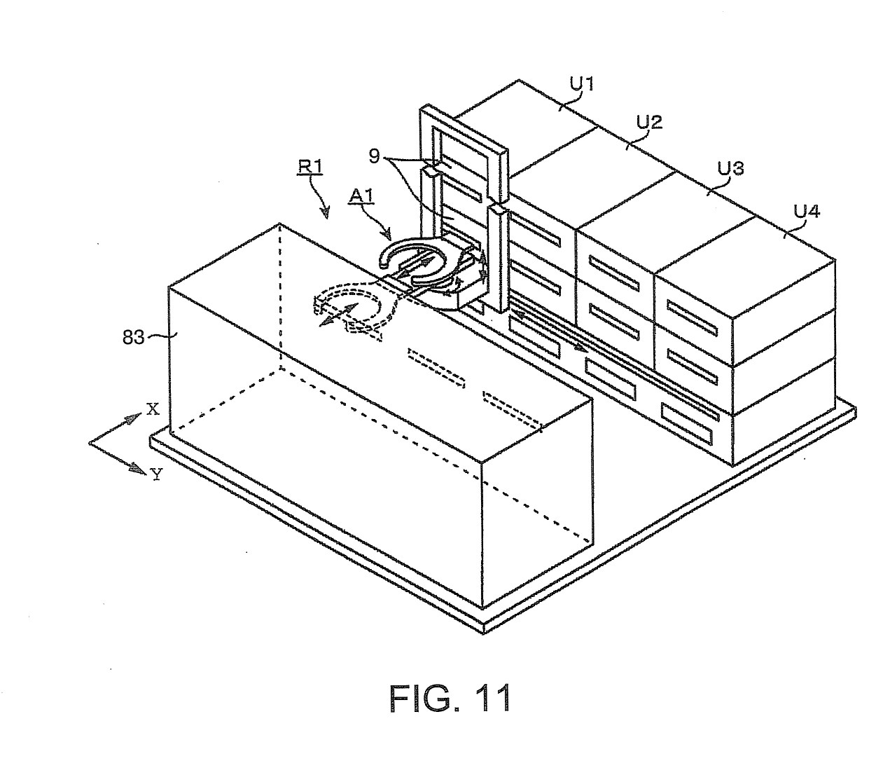

The first block (DEV layer) B1 has two development modules 83 (corresponding to the resist film formation module) laminated. Each development module 83 has three development sections 91 and a housing that houses the development sections 91. The first block (DEV layer) B1 includes the shelf units U1 to U4 that form a heating/cooling treatment module group that performs processes before and after processes performed by the development modules 83. FIG. 11 is a perspective view of a module including the development module 83 (located on the lower side of the first block (DEV layer) B1) and the shelf units U1 to U4 that are arranged opposite to the development module 83. The shelf units U3 and U4 form a heating module 9 corresponding to the aforementioned heating apparatus 1.

The first block (DEV layer) B1 includes a transfer arm A1 as shown in FIG. 11. The transfer arm A1 transfers the wafer W between the two development modules and the heating/cooling treatment module. The transfer arm A1 is shared by the two development modules and corresponds to the aforementioned substrate transfer unit.

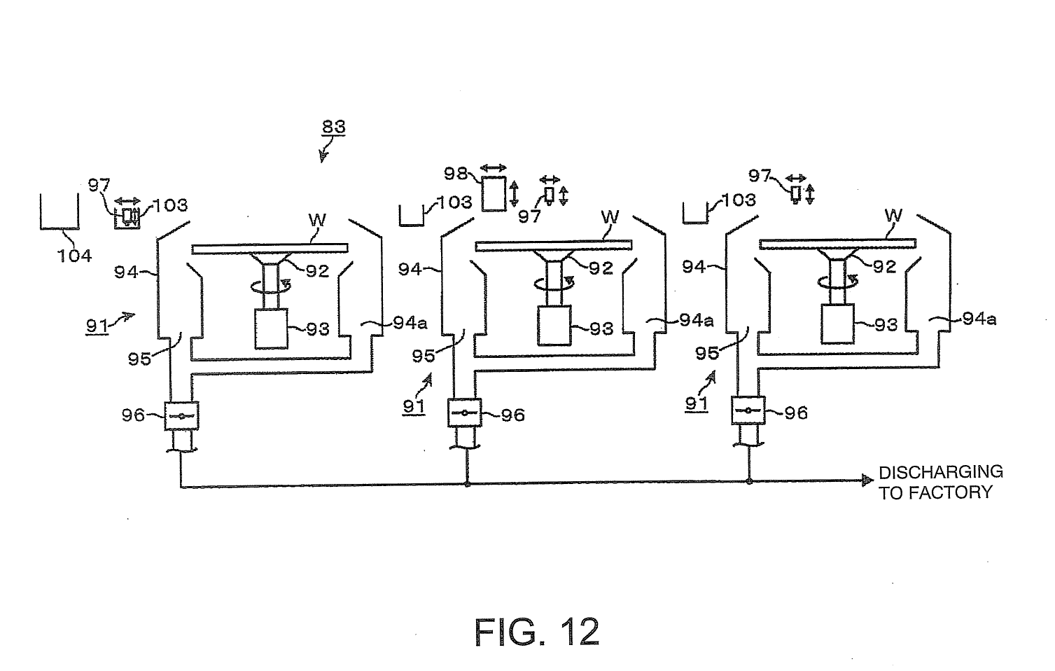

The development module 83 is described below with reference to FIG. 12 showing an outline configuration of the development module 83. Each development section 91 includes a spin chuck 92, a rotation driving mechanism 93, and a cup body 94. The spin chuck 92 serves as a substrate holding section and sucks a central portion of the back surface of the wafer W to hold the wafer W so that the wafer W is horizontally-oriented. The rotation driving mechanism 93 causes the wafer W to rotate around a vertical axis through the spin chuck 92. The cup body 94 surrounds the wafer W held by the spin chuck 92.

The cup body 94 has a liquid receiver 94a located on the side of a bottom portion of the cup body 94. The liquid receiver 94a is formed in a concave shape. The liquid receiver 94a is partitioned into an outer region and an inner region by a partition wall (not shown) on the lower side of an edge portion of the wafer W. The outer and inner regions of the liquid receiver 94a extend along the whole circumference of the liquid receiver 94a. The outer region includes a waste liquid port (not shown) in a bottom portion of the outer region. A stored developer or the like is discharged from the waste liquid port. The inner region includes a discharge port 95 on a bottom portion of the inner region. A treatment atmosphere is discharged from the discharge port 95. The discharge port 95 is connected to a discharge path of a factory through a discharge dumper 96 that controls the amount of a gas (that is to be discharged) included in the cup body 94. A lifting pin (not shown) is provided in the cup body 94 and transfers the wafer W between the transfer arm A1 and the spin chuck 92.

Each development section 91 has a pure water supply nozzle 97 that supplies pure water or the like as a cleaning liquid to clean the wafer W having the developer thereon. A developer supply nozzle 98 supplies the developer onto the wafer W and is shared by the development sections 91. The nozzles 97 and 98 are connected to respective driving mechanisms and driven by the respective driving mechanisms to move independently from each other in a direction in which the development sections 91 are arranged and to move up and down independently from each other. In FIG. 12, reference numerals 103 and 104 denote stand-by units. The nozzles 97 stand by in the respective stand-by units 103 when a process is not performed on the wafer W. The nozzle 98 stands by in the stand-by unit 104 when a process is not performed on the wafer W.

The coating and developing apparatus 8 is described below again. The treatment block C2 also includes a shelf unit U5 as shown in FIGS. 8 and 10. The shelf unit 5 has transfer units. One of the transfer units included in the shelf unit 5 is a transfer unit CPL2 that is provided for the second block (BCT layer) B2. The wafer W is transferred from the carrier block C1 to the transfer unit CPL2, for example. The second block (BCT layer) B2 includes a transfer arm A2. The transfer arm A2 receives the wafer W from the transfer unit CPL2 and transfers the wafer W to the units (antireflective film formation module and heating/cooling treatment module group). The units form the antireflective film on the wafer W.

After that, the wafer W is transferred through a transfer unit BF2 and a transfer arm D1 to a transfer unit CPL3. The transfer unit BF2 and the transfer unit CPL3 are included in the shelf unit U5. The temperature of the wafer W is adjusted to, for example, 23 degrees C. in the transfer unit CPL3. Then, the wafer W is transferred to the third block (COT layer) B3 through a transfer arm A3 included in the third block (COT layer) B3. The wafer W is then transferred to the resist film formation module. The resist film is formed on the wafer W in the resist film formation module. The wafer W is then transferred from the transfer arm A3 to a transfer unit BF3 included in the shelf unit U5. In the fourth block (ITC layer) B4, the protective film is formed on the wafer W having the resist film formed thereon in some cases. In this case, the wafer W is transferred through a transfer unit CPL4 (included in the shelf unit U5) to a transfer arm A4 (included in the fourth block (ITC layer) B4). After the protective film is formed on the wafer W, the wafer W is transferred from the transfer arm A4 to a transfer unit TRS4 (included in the shelf unit U5).

The first block (DEV layer) B1 includes a shuttle arm 85. The shuttle arm 85 serves as a dedicated transfer arm to transfer the wafer W directly from a transfer unit CPL11 to a transfer unit CPL12. The transfer unit CPL11 is included in the shelf unit U5. The transfer unit CPL12 is included in a shelf unit U6. The wafer W having the resist film (and the protective film) formed thereon is transferred through the transfer arm D1, the transfer unit BF3 and the transfer unit TRS4 to the transfer unit CPL11. The wafer W is directly transferred from the transfer unit CPL11 to the transfer unit CPL12 through the shuttle arm 85. The wafer W is then transferred from the transfer unit CPL12 into an interface block C3. Each of the transfer units (shown in FIG. 10) denoted by the symbol starting with “CPL” also serves as a cooling unit for temperature adjustment. Each of the transfer units (shown in FIG. 10) denoted by the symbol starting with “BF” also serves as a buffer unit capable of mounting a plurality of wafers W.

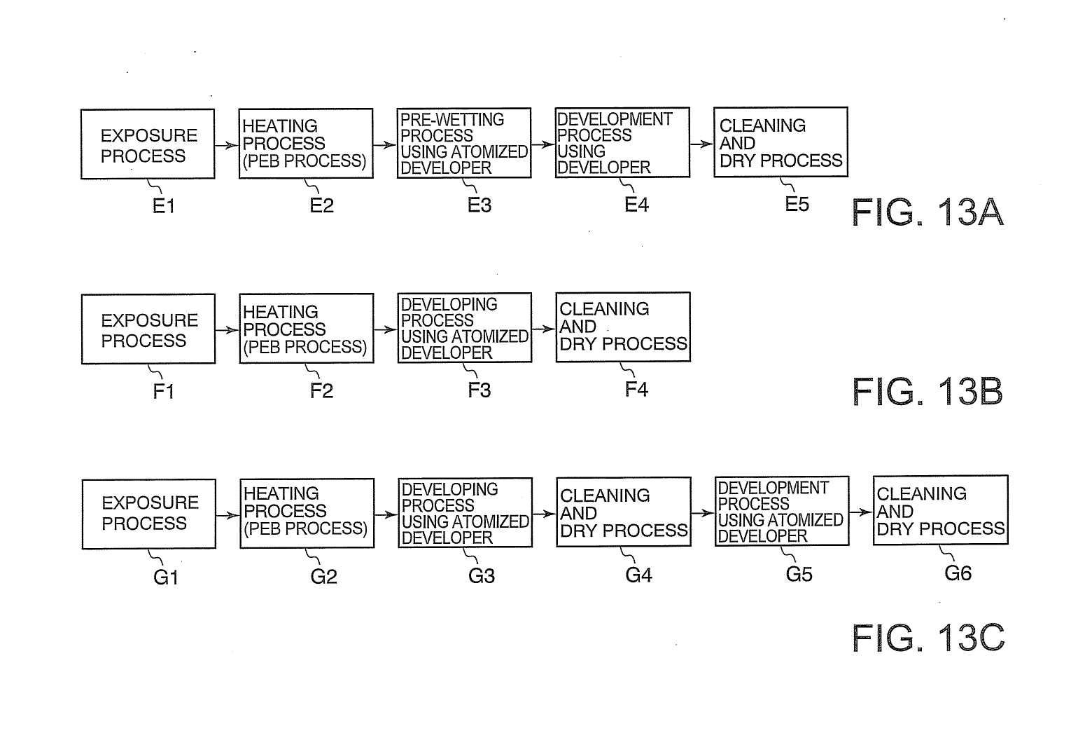

Processes that are performed after exposure by the coating and developing apparatus 8 are described below with reference to FIG. 13A. After the wafer W is transferred to the transfer unit CPL12, the wafer W is transferred to the exposure apparatus C4 by an interface arm 86. The exposure apparatus C4 performs a predetermined exposure process (step E1) on the wafer W. After the exposure process, the wafer W is placed on a transfer unit TRS6 included in the shelf unit U6 and then returned back to the treatment block C2. The wafer W is then subjected to the heating process (step E2) (PEB process) by the heating module 9 and subjected to the pre-wetting process (step E3) by means of the atomized developer. After that, the wafer W is transferred to one of the development sections 91 by the transfer arm A1. Then, the wafer W is transferred to the spin chuck 92. Steps E2 and E3 correspond to respective steps S2 and S3 described in the explanation of the heating apparatus 1.

The developer supply nozzle 98 supplies the developer onto the wafer W rotating by means of the spin chuck 92 while moving from an edge portion of the surface of the wafer W to the central portion of the surface of the wafer W so that a liquid film made of the developer is formed on the surface of the wafer W (step E4). After that, the pure water supply nozzle 97 supplies the pure water onto the central portion of the surface of the wafer W. The pure water spreads toward the edge portion of the surface of the wafer W due to centrifugal force of the rotating wafer W. After the developer is rinsed, the supply of the pure water is stopped. The pure water is drained off from the wafer W due to the rotation of the wafer W so that the wafer W becomes dry (step E5). The dry wafer W is transferred to a transfer unit TRS1 included in the shelf unit U5 by the transfer arm A1. The dry wafer W is then returned back to the carrier 80 through the transfer arm 82.

In the coating and developing apparatus 8, the development modules 83 do not need to perform the pre-wetting process on the wafer W. Thus, the processes performed by the developer modules 83 are simplified compared with the case where the development modules 83 perform the pre-wetting process. The nozzles 97 and 98 do not need to move for the pre-wetting process. Thus, loads of the driving mechanisms that cause the respective nozzles to move are reduced. Therefore, the process from the transfer of the wafer W to the cleaning of the wafer W in each development module 83 can be performed for a shorter time. As a result, a reduction in the throughput can be suppressed.

To perform the development process in the heating module 9 instead of the pre-wetting process, a cleaning module is provided in the first block (DEV layer) B1 instead of the development modules 83. The cleaning module does not include the developer supply nozzle 98. Other parts of the cleaning module are the same as those of the development module 83. The development process that is to be performed by the heating module 9 is described below with reference to a flowchart shown in FIG. 13B. In the description, differences between the development process and the pre-wetting process are mainly described.

First, an exposure process (step F1) and a heating process (step F2) are performed in the same way as the steps E1 and E2. After that, the heating module 9 performs a development process (step F3) so that the atomized developer is supplied onto the wafer W to form a liquid film made of the developer on the entire surface of the wafer W. After that, the transfer arm A1 transfers the wafer W to the cleaning module. Then, a cleaning and dry process (step F4) is performed on the wafer W in the same way as the step E5 performed in each development module 83. The process shown in FIG. 13B simplifies a process that is performed by a module located at the subsequent stage of the heating module 9. Thus, a reduction in the throughput can be reliably suppressed.

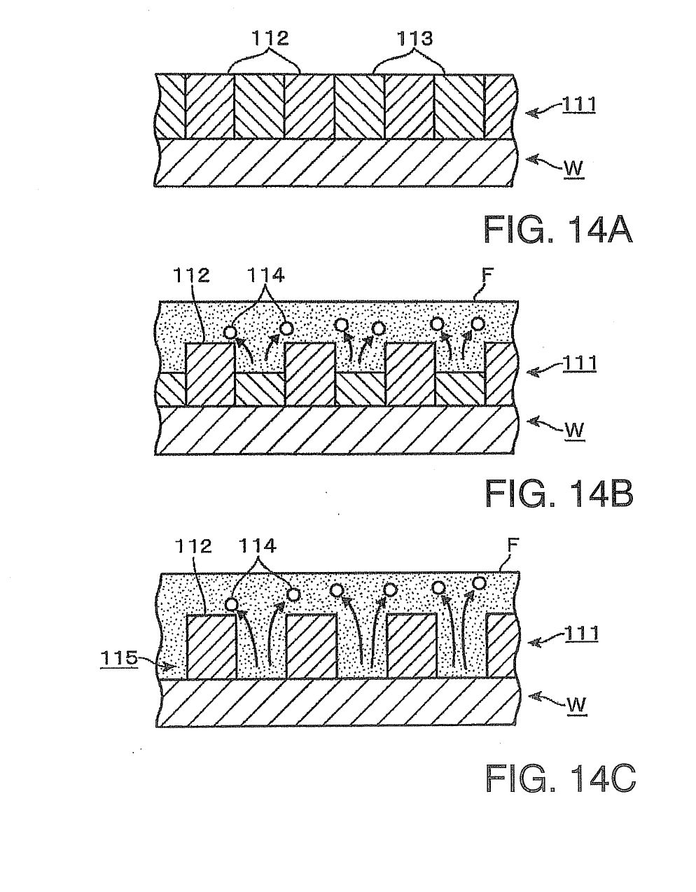

The inventors of the present invention verified that: a portion of the resist is not dissolved into the developer only by contacting the portion of the resist with the developer; the developer remains on the surface of the resist film; and there is a tendency that the portion of the resist is dissolved into the developer when the cleaning liquid such as pure water is supplied onto the wafer W after the supply of the developer and the solution of the portion of the resist progresses. In some cases, a time required for the actual development process is longer than a time (for the development process) estimated on the basis of materials contained in the resist. The inventors consider that in this case, the development is affected by this effect (solution), and it takes time for the developer to flow into the resist in a vertical direction (direction in which the depth of the resist film is measured). In addition, the inventors consider that when the resist pattern is finer, this effect is more significant. In order to avoid the effect, the amount of consumption of the developer is suppressed, and the time required for the development process is suppressed. To suppress the amount of the developer and the time required for the development process, the developer and the pure water are alternately supplied onto the wafer W by the coating and developing apparatus 8 having the cleaning module. The method for alternately supplying the developer and the pure water onto the wafer W is described with reference to FIGS. 13C, 14A, 14B and 14C. FIG. 13C is a flowchart of the method. FIGS. 14A to 14C are side views of the wafer W and schematically show changes in the surface of the wafer W. Differences between the coating and development method described above and the method for alternately supplying the developer and the pure water onto the wafer W are mainly described below.

In the same way as the steps E1 and E2, an exposure process (step G1) is performed, and a heating process (step G2) is then performed by the heating module 9. FIG. 14A shows the surface of the wafer W subjected to the exposure process (step G1). In FIG. 14A, reference numeral 111 denotes the resist film; reference numeral 112 denotes a portion of the resist film, which is insoluble in the developer; and reference numeral 113 denotes a portion of the resist film, which is soluble in the developer. After the heating process (step G2), a development process (step G3) is performed so that the atomized developer is supplied onto the wafer W and a liquid film made of the developer is formed on the entire surface of the wafer W, in the same way as the step F3.

After that, the transfer arm A1 transfers the wafer W to the cleaning module. The pure water supply nozzle 97 supplies pure water F onto the central portion of the surface of the rotating wafer W. An upper part of the soluble portion 113 that contacts the developer is rinsed and removed from the resist film 111. FIG. 14B shows the surface of the wafer W after the upper part of the soluble portion 113 that contacts the developer is removed from the resist film 111. In FIG. 14B, reference numeral 114 denotes a dissolved resist portion.

After the cleaning, the pure water is drained off so that the wafer W becomes dry (step G4). The wafer W is then transferred from the transfer arm A1 to the heating module 8. The atomized developer is supplied onto the wafer W in the heating module 8 to form a liquid film made of the developer on the surface of the wafer W (step G5). The transfer arm A1 transfers the wafer W to the cleaning module. The pure water F is supplied onto the wafer W rotating in the cleaning module. As shown in FIG. 14C, the soluble portion 113 that contacts the developer is dissolved so that a resist pattern 115 is formed. The dissolved resist portion 114 is rinsed by the pure water F and removed from the resist film 111. After that, the pure water is drained off from the wafer W due to the rotation of the wafer W so that the wafer w becomes dry (step G6).

In addition to the effects described in the embodiment, the soluble portion can contact the developer in an efficient manner in the aforementioned development process, since after the upper part of the soluble portion that contacts the developer is removed, the developer is supplied onto the wafer W so that an upper part or all parts of the remaining soluble portion, which contacts or contact the developer, is or are removed. Thus, the amount of the developer to be used can be reduced, and the time required for the development process can be suppressed. In addition, the development can be performed with high resolution. The method for alternately supplying the developer and the pure water may be performed two or more times.

What is claimed is:

1. A substrate treatment apparatus comprising:
a housing;
a heating plate that is located in the housing, the heating plate heating a substrate prepared by coating a surface of the substrate with a resist and exposing the resist-coated substrate to light;
means for atomizing a surface treatment liquid used to improve wettability of the substrate with a developer that is supplied onto the resist;
cooling means that is located in association with the heating plate, the cooling means cooling the substrate heated by the heating plate; and
surface treatment liquid supply means that is connected to the surface treatment liquid atomizing means, the surface treatment liquid supply means supplying the atomized surface treatment liquid onto the substrate for a portion of the period from the time when the heating plate starts heating the substrate until the cooling means terminates the cooling of the substrate.

2. The substrate treatment apparatus according to claim 1, further comprising
means for controlling the surface treatment liquid supply means such that the atomized surface treatment liquid is supplied onto the substrate during a portion of the period when the heating plate heats the substrate.

3. The substrate treatment apparatus according to claim 1,
wherein the heating plate also serves as a stage on which the substrate is mounted;
the cooling means is a cooling plate capable of moving between an upper region defined above the heating plate and a region to which the cooling plate retreats from the upper region.

4. The substrate treatment apparatus according to claim 1,
wherein the cooling means cools the substrate in such a manner as to hold the substrate, locate the substrate in an upper region defined above the heating plate for heating, move the substrate between the upper region and a region to which the cooling means retreats from the upper region, and cause the heated substrate to retreat from the upper region.

5. A substrate treatment apparatus comprising:
a housing;
a heating plate that is located in the housing, the heating plate heating a substrate prepared by coating a surface of the substrate with a resist and exposing the resist-coated substrate to light;
means for atomizing a developer;
cooling means that is located in association with the heating plate, the cooling means cooling the substrate heated by the heating plate; and
developer supply means that is connected to the developer atomizing means, the developer supply means supplying the atomized developer onto the substrate for a portion of the period from the time when the heating plate starts heating the substrate until the cooling means terminates the cooling of the substrate.

6. The substrate treatment apparatus according to claim 5, further comprising
means for controlling the developer supply means such that the atomized developer is supplied onto the substrate during a portion of the period when the heating plate heats the substrate.

7. The substrate treatment apparatus according to claim 5,
wherein the heating plate also serves as a stage on which the substrate is mounted;
the cooling means is a cooling plate capable of moving between an upper region defined above the heating plate and a region to which the cooling plate retreats from the upper region.

8. The substrate treatment apparatus according to claim 5,
wherein the cooling means cools the substrate in such a manner as to hold the substrate, locate the substrate in an upper region defined above the heating plate for heating, move the substrate between the upper region and a region to which the cooling means retreats from the upper region, and cause the heated substrate to retreat from the upper region.

9. A substrate treatment method comprising, the steps of:
heating a substrate prepared by coating a surface of the substrate with a resist and exposing the resist-coated substrate to light;
atomizing a surface treatment liquid used to improve wettability of the substrate with a developer that is supplied onto the resist;
cooling the heated substrate by cooling means; and
supplying the atomized surface treatment liquid onto the substrate for a portion of the period from the time when the substrate is heated until the cooling means terminates the cooling of the substrate.

10. The substrate treatment method according to claim 9, further comprising the step of supplying the atomized surface treatment liquid onto the substrate during the step of heating the substrate.

11. A substrate treatment method comprising, the steps of:
heating a substrate prepared by coating a surface of the substrate with a resist and exposing the resist-coated substrate to light;
atomizing a developer;
cooling the heated substrate by cooling means; and
supplying the atomized developer onto the substrate for a portion of the period from the time when the substrate is heated until the cooling means terminates the cooling of the substrate.

12. The substrate treatment method according to claim 11, further comprising the step of supplying the atomized developer onto the substrate during the step of heating the substrate.

13. A coating and developing apparatus comprising:
a carrier block having a carrier capable of holding a plurality of substrates and transferring the substrates into and out of the carrier block;
a treatment block including a coating section that coats a resist on the surface of each substrate taken out of the carrier, a heating section that heats the resist-coated substrate subjected to an exposure process, a development section that supplies a developer onto the heated substrate to develop the substrate, and means for transferring the substrate among the coating section, the heating section, and the development section; and
an interface block that transfers the substrate between the treatment block and an exposure apparatus that exposes the resist to light,
wherein the heating section includes:
a housing;
a heating plate that is located in the housing, the heating plate heating the substrate prepared by coating the surface of the substrate with the resist and exposing the resist-coated substrate to light;
means for atomizing a surface treatment liquid used to improve wettability of the substrate with the developer that is supplied onto the resist;
cooling means that is located in association with the heating plate, the cooling means cooling the substrate heated by the heating plate; and
surface treatment liquid supply means that is connected to the surface treatment liquid atomizing means, the surface treatment liquid supply means supplying the atomized surface treatment liquid onto the substrate for a portion of the period from the time when the heating plate starts heating the substrate until the cooling means terminates the cooling of the substrate; and
wherein the treatment block includes a cleaning section that supplies a cleaning liquid onto the substrate supplied with the developer by the development section to remove the developer from the substrate.

14. A coating and developing apparatus comprising:
a carrier block having a carrier capable of holding a plurality of substrates and transferring the substrates into and out of the carrier block;
a treatment block including a coating section that coats a resist on the surface of each substrate taken out of the carrier, a heating section that heats the resist-coated substrate subjected to an exposure process, a cleaning section that supplies a cleaning liquid to the substrate supplied with the developer to remove the developer from the substrate, and means for transferring the substrate among the coating section, the heating section, and the cleaning section; and
an interface block that transfers the substrate between the treatment block and an exposure apparatus that exposes the resist to light;
wherein the heating section includes:
a housing;
a heating plate that is located in the housing, the heating plate heating the substrate prepared by coating the surface of the substrate with the resist and exposing the resist-coated substrate to light;
means for atomizing the developer;
cooling means that is located in association with the heating plate, the cooling means cooling the substrate heated by the heating plate; and
developer supply means that is connected to the developer atomizing means, the developer supply means supplying the atomized developer onto the substrate for a portion of the period from the time when the heating plate starts heating the substrate until the cooling means terminates the cooling of the substrate.

15. The coating and developing apparatus according to claim 14,
wherein a process for supplying the atomized developer onto the substrate by means of the heating section and a process for supplying the cleaning liquid onto the substrate by means of the cleaning section are alternately repeated.

16. A coating and developing method using a coating and developing apparatus, the apparatus comprising:
a carrier block having a carrier capable of holding a plurality of substrates and transferring the substrates into and out of the carrier block;
a treatment block including a coating section that coats a resist on the surface of each substrate taken out of the carrier, a heating section that heats the resist-coated substrate subjected to an exposure process, a development section that supplies a developer onto the heated substrate to develop the substrate, and means for transferring the substrate among the coating section, the heating section, and the development section; and
an interface block that transfers the substrate between the treatment block and an exposure apparatus that exposes the resist to light;
the coating and developing method comprising the steps of:
heating the substrate prepared by coating the surface of the substrate with the resist and exposing the resist-coated substrate to light;
atomizing a surface treatment liquid used to improve wettability of the substrate with the developer that is supplied onto the resist;
cooling the heated substrate by cooling means;
supplying the atomized surface treatment liquid onto the substrate for a portion of the period from the time when the substrate is heated until the cooling means terminates the cooling of the substrate; and
supplying a cleaning liquid onto the substrate supplied with the developer by the development section to remove the developer from the substrate.

17. A coating and developing method using a coating and developing apparatus, the apparatus comprising:
a carrier block having a carrier capable of holding a plurality of substrates and transferring the substrates into and out of the carrier block;
a treatment block including a coating section that coats a resist on the surface of each substrate taken out of the carrier, a heating section that heats the resist-coated substrate subjected to an exposure process, a cleaning section that supplies a cleaning liquid onto the substrate supplied with a developer to remove the developer from the substrate, and means for transferring the substrate among the coating section, the heating section, and the cleaning section; and
an interface block that transfers the substrate between the treatment block and an exposure apparatus that exposes the resist to light,
the coating and developing method comprising the steps of:
heating the substrate prepared by coating the surface of the substrate with the resist and exposing the resist-coated substrate to light;
atomizing the developer;
cooling the heated substrate by cooling means; and
supplying the atomized developer onto the substrate for a portion of the period from the time when the substrate is heated until the cooling means terminates the cooling of the substrate.

18. The coating and developing method according to claim 17,
wherein the step of supplying the atomized developer onto the substrate and the step of supplying the cleaning liquid onto the substrate are alternately repeated.

19. A storage medium having a computer program stored, the program being used for a substrate treatment apparatus that heats a substrate,
wherein the computer program is designed to perform a substrate treatment method, the method including the steps of:
heating the substrate prepared by coating a surface of the substrate with a resist and exposing the resist-coated substrate to light;
atomizing a surface treatment liquid used to improve wettability of the substrate with a developer that is supplied onto the resist;
cooling the heated substrate by cooling means; and
supplying the atomized surface treatment liquid onto the substrate for a portion of the period from the time when the substrate is heated until the cooling means terminates the cooling of the substrate.

20. A storage medium having a computer program stored, the program being used for a substrate treatment apparatus that heats a substrate,
wherein the computer program is designed to perform a substrate treatment method, the method including the steps of:
heating the substrate prepared by coating a surface of the substrate with a resist and exposing the resist-coated substrate to light;
atomizing a developer;
cooling the heated substrate by cooling means; and
supplying the atomized developer onto the substrate for a portion of the period from the time when the substrate is heated until the cooling means terminates the cooling of the substrate.
